(19) United States
(12) Patent Application Publication
(10) Pub. No.: US 2025/0149482 A1
(43) Pub. Date: May 8, 2025

(54) SEMICONDUCTOR STRUCTURE WITH BONDING INTERFACE AND METHODS OF FORMING THE SAME

(71) Applicant: Taiwan Semiconductor Manufacturing Co., Ltd., Hsinchu (TW)

(72) Inventors: Yi-Shan Hsieh, Hsinchu (TW); Chen-Chiu Huang, Taichung City (TW); Yu-Bey Wu, Hsinchu (TW); Hsiang-Ku Shen, Hsinchu (TW); Dian-Hau Chen, Hsinchu (TW)

(21) Appl. No.: 18/587,104

(22) Filed: Feb. 26, 2024

Related U.S. Application Data
(60) Provisional application No. 63/595,568, filed on Nov. 2, 2023.

(51) Int. Cl. H01L 23/00; H01L 21/768; H01L 23/522; H01L 23/528

(52) U.S. Cl. CPC H01L 24/08; H01L 21/76804; H01L 21/76819; H01L 21/7684; H01L 21/76871; H01L 21/76877; H01L 23/5226; H01L 23/528; H01L 24/80; H01L 2224/08145; H01L 2224/80895; H01L 2224/80896

(57) ABSTRACT

In an embodiment, a method includes forming active devices over a semiconductor substrate; forming an interconnect structure over the semiconductor substrate, the interconnect structure comprising a contact pad embedded in a dielectric layer; forming a first passivation layer over the interconnect structure; forming a first opening through the first passivation layer to expose the contact pad; depositing a seed layer over the first passivation layer and in the first opening; forming a sacrificial material over the seed layer; patterning the sacrificial material to reform the first opening and to form a second opening; depositing conductive material to form a first redistribution line in the first opening and a second redistribution line in the second opening; removing the sacrificial material; and attaching an integrated circuit die to the first redistribution line and the second redistribution line.

### PRIORITY CLAIM AND CROSS-REFERENCE

This application claims the benefit of U.S. Provisional Application No. 63/595,568, filed on Nov. 2, 2023, which application is hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller semiconductor dies with more components has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-10 are cross-sectional views of intermediate stages in the manufacturing of an integrated circuit die, in accordance with some embodiments.

FIGS. 11-14 are cross-sectional views of intermediate stages in the manufacturing of an integrated circuit die, in accordance with some embodiments.

FIGS. 15-16 are cross-sectional views of intermediate stages in the manufacturing of a die structure, in accordance with some embodiments.

FIGS. 17-18D are plan views of bonding surfaces of a die structure, in accordance with some embodiments.

FIGS. 18-19 are cross-sectional views of intermediate stages in the manufacturing of a die structure, in accordance with some embodiments.

FIGS. 21-22D are plan views of bonding surfaces of a die structure, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The disclosure provides various embodiments of integrated circuit dies and die structures incorporating the integrated circuit dies, as well as methods of forming the same. According to various embodiments of a first integrated circuit die, an interconnect structure is formed over an active device layer. Redistribution lines are formed over the interconnect structure and embedded in a passivation layer. The redistribution lines and the passivation layer are then processed to be configured for direct bonding with conductive features and a dielectric layer of a second integrated circuit die. For example, a planarization process is used to remove upper portions of the redistribution lines and the passivation layer resulting in substantially level upper surfaces of the redistribution lines and the passivation layer. The conductive features of the second integrated circuit die may be die connectors (e.g., bond pads) or redistribution lines. The dielectric layer of the second integrated circuit die may be a passivation layer or a dielectric bond layer. The first integrated circuit die and the second integrated circuit die may be directly bonded to one another without forming die connectors and a dielectric bond layer over the first integrated circuit die and, optionally, also without forming die connectors and a dielectric bond layer over the second integrated circuit die. The integrated circuit die(s) may be fabricated with fewer steps and at a greater yield, which may further result in the integrated circuit die(s) being thinner, having greater bonding density (e.g., smaller bonding pitch), and having an improved performance. Consequently, analogous advantages are achieved for the die structures that incorporate the integrated circuit die(s).

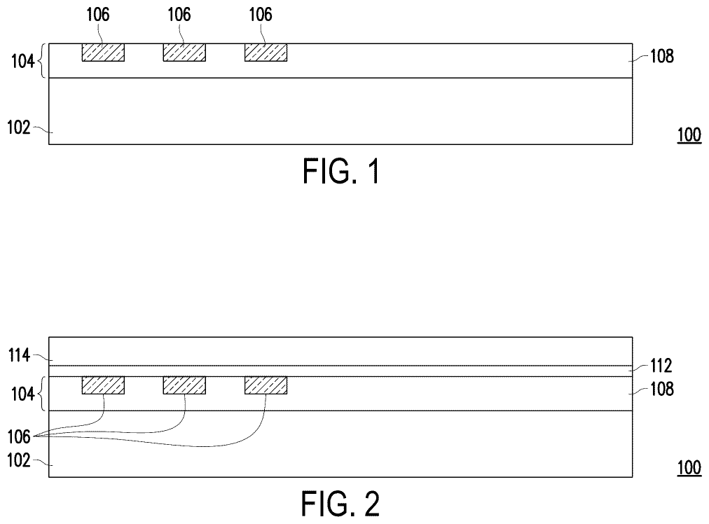

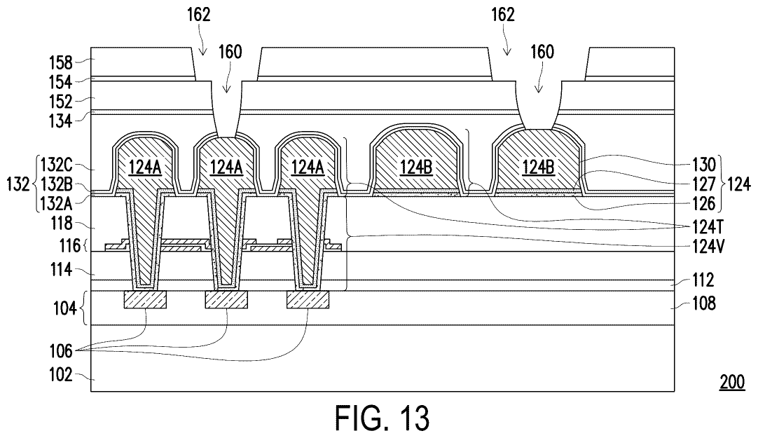

FIGS. 1 through 10 are cross-sectional views of intermediate stages in the manufacturing of an integrated circuit die 100 (see FIG. 10), in accordance with some embodiments. The integrated circuit die 100 may be a logic device (e.g., central processing unit (CPU), graphics processing unit (GPU), microcontroller, etc.), a memory device (e.g., dynamic random access memory (DRAM) die, static random access memory (SRAM) die, etc.), a power management device (e.g., power management integrated circuit (PMIC) die), a radio frequency (RF) device, a sensor device, a micro-electro-mechanical-system (MEMS) device, a signal processing device (e.g., digital signal processing (DSP) die), a front-end device (e.g., analog front-end (AFE) die), the like, or combinations thereof (e.g., a system-on-a-chip (SoC) die). The integrated circuit die 100 may be formed in a wafer, which may include different device regions that are singulated in subsequent steps to form a plurality of integrated circuit dies 100.

In FIG. 1, a semiconductor substrate 102 is formed or provided. The semiconductor substrate 102 may be a silicon substrate, doped or undoped, or an active layer of a semiconductor-on-insulator (SOI) substrate. The semiconductor substrate 102 may include other semiconductor materials, such as germanium; a compound semiconductor including silicon carbide, gallium arsenic, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used. The semiconductor substrate 102 has an active surface (e.g., the surface facing upwards in FIG. 1), sometimes called a front side, and an inactive surface (e.g., the surface facing downwards in FIG. 1), sometimes called a back side. A device layer (not specifically illustrated) is formed at the active surface of the semiconductor substrate 102. The device layer may include devices such as active devices (e.g., transistors, diodes, etc.) or passive devices (e.g., capacitors, inductors, resistors, etc.). The inactive surface may be free of devices. The device layer may be formed in a suitable front-end of line (FEOL) process.

An interconnect structure 104 is formed over the active surface of the semiconductor substrate 102. The interconnect structure 104 interconnects the devices of the semiconductor substrate 102 to form an integrated circuit. The interconnect structure 104 may be formed in a suitable back-end of line (BEOL) process. The interconnect structure 104 may include one or more dielectric layer(s) and respective metallization pattern(s) in the dielectric layer(s). Acceptable dielectric materials for the dielectric layers include oxides such as silicon oxide, aluminum oxide, or the like; nitrides such as silicon nitride, silicon oxynitride; combinations thereof; or the like. The dielectric layer(s) may be formed of a low-k (LK) dielectric material such as carbon-doped silicon oxide, an extremely low-k (ELK) dielectric material such as porous carbon-doped silicon oxide, or the like. Other acceptable dielectric materials may be utilized. The metallization patterns may include conductive vias and/or conductive lines to interconnect the devices of the semiconductor substrate 102. The metallization patterns may be formed of a conductive material, such as a metal, such as copper, cobalt, aluminum, gold, combinations thereof, or the like. The metallization patterns may be formed by a damascene process, such as a single damascene process, a dual damascene process, or the like.

Contact pads 106 are formed at the front side of the integrated circuit die 100. The contact pads 106 may be pads, conductive pillars, or the like, to which external connections are made. The contact pads 106 may be in and/or on the interconnect structure 104. For example, the contact pads 106 may be part of an upper metallization pattern of the interconnect structure 104. The contact pads 106 can be formed of a metal, such as copper, aluminum, a copper alloy, combinations thereof, or the like, which can be formed by, for example, plating, or the like. In some embodiments, the contact pads 106 are part of the upper metallization layer of the interconnect structure 104 and are formed similarly as described with respect to other metallization layers of the interconnect structure 104.

A dielectric layer 108 is at the front side of the integrated circuit die 100. The dielectric layer 108 may be in and/or on the interconnect structure 104. For example, the dielectric layer 108 may be an upper dielectric layer of the interconnect structure 104. The dielectric layer 108 laterally surrounds the contact pads 106. The dielectric layer 108 may be an oxide, a nitride, a polymer, the like, or a combination thereof. The dielectric layer 108 may be formed, for example, by spin coating, lamination, chemical vapor deposition (CVD), or the like.

In some embodiments (not separately illustrated), the integrated circuit die 100 is a stacked device that includes multiple semiconductor substrates 102. For example, the integrated circuit die 100 may be a memory device that includes multiple memory dies, such as a hybrid memory cube (HMC) module, a high bandwidth memory (HBM) module, or the like. In such embodiments, the integrated circuit die 100 includes multiple semiconductor substrates 102 interconnected by through-substrate vias (TSVs), such as through-silicon vias. Each of the semiconductor substrates 102 may (or may not) have an interconnect structure 104.

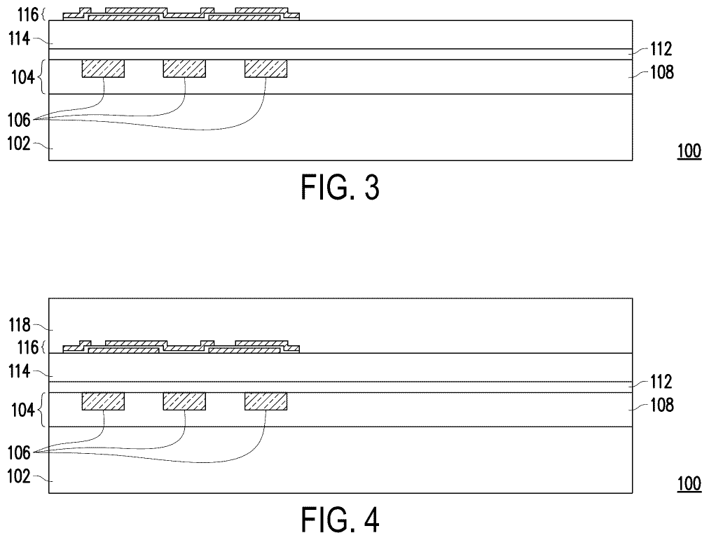

In FIG. 2, a passivation layer 114 is formed over the interconnect structure 104 (e.g., over the dielectric layer 108 and the contact pads 106). The passivation layer 114 may be formed of one or more acceptable dielectric materials, such as silicon nitride, silicon oxide, combinations thereof, or the like. Other acceptable dielectric materials include polymers such as polyimide, solder resist, polybenzoxazole (PBO), a benzocyclobutene (BCB) based polymer, molding compound, or the like. The passivation layer 114 may be formed by deposition (e.g., CVD), spin coating, lamination, combinations thereof, or the like. The passivation layer 114 may be formed to a large thickness, such as a thickness in the range of 2 kÅ to 10 kÅ. Additionally, the passivation layer 114 may be planarized, such as by a chemical mechanical polish (CMP) process.

An etch stop layer 112 is formed between the passivation layer 114 and the interconnect structure 104. The etch stop layer 112 may be formed of a dielectric material having a high etching selectivity from the etching of the passivation layer 114, such as silicon nitride, silicon carbonitride, silicon oxynitride, or the like, which may be formed by any suitable deposition process, such as CVD, atomic layer deposition (ALD), or the like. In accordance with some embodiments, the etch stop layer 112 comprises silicon carbonitride and the passivation layer 114 comprises silicon nitride.

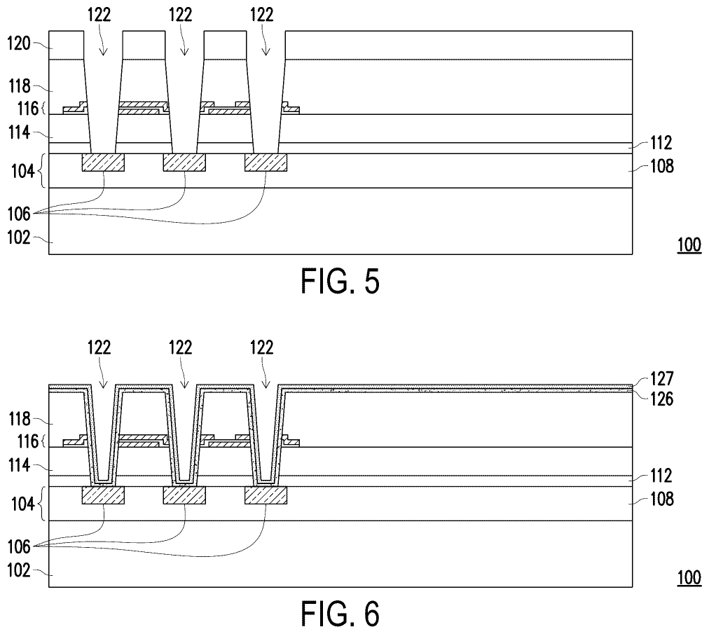

In FIG. 3, passive devices 116 are optionally formed on the passivation layer 114. The passive devices 116 may include capacitors, inductors, resistors, and the like. The passive devices 116 are embedded passive devices, and may be electrically coupled to the devices of the semiconductor substrate 102. In some embodiments, one or more of the passive devices 116 may have a metal-insulator-metal (MIM) structure that includes one or more metal layer(s) and one or more insulating layer(s) (not separately labeled). The integrated circuit die 100 may include any desired combination and quantity of the illustrated passive devices 116.

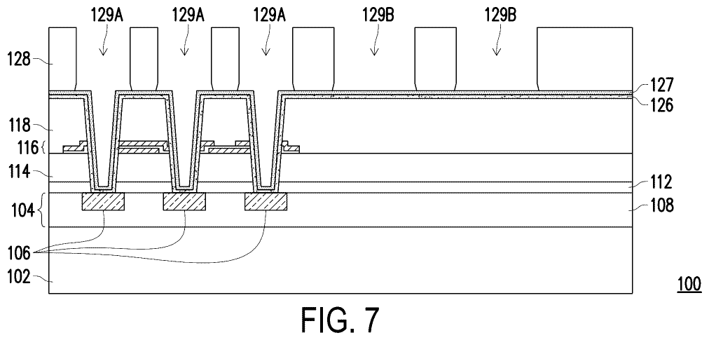

In FIG. 4, a passivation layer 118 is formed over the passive devices 116 (if present) and the passivation layer 114. The passivation layer 118 may be formed of one or more acceptable dielectric materials, such as silicon nitride, silicon oxide, combinations thereof, or the like. Other acceptable dielectric materials include polymers such as polyimide, solder resist, PBO, a BCB based polymer, molding compound, or the like. The passivation layer 118 may be formed by deposition (e.g., CVD), spin coating, lamination, combinations thereof, or the like. The passivation layer 118 may be formed to a large thickness and then planarized, such as by a CMP process. In accordance with some embodiments, the passivation layer 118 comprises a same or similar material as the passivation layer 114, such as silicon nitride.

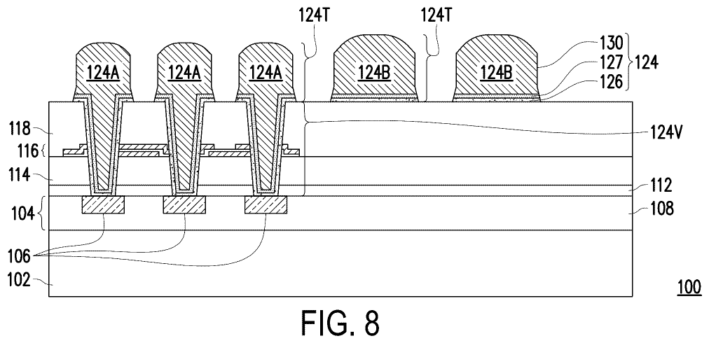

In FIG. 5, openings 122 are patterned through the passivation layer 118, the passivation layer 114, and the etch stop layer 112, thereby exposing the contact pads 106. The openings 122 may be formed using acceptable photolithography and etching techniques. For example, a photoresist 120 may be formed and patterned over the passivation layer 118 to include upper openings 122. The photoresist 120 may be formed by spin coating or the like and may be exposed to light for patterning. The pattern of the photoresist 120 corresponds to the contact pads 106. The patterning forms the openings 122 directly over the contact pads 106. The openings 122 may then be extended through the various layers (e.g., the passivation layer 118, the passivation layer 114, and the etch stop layer 112) by one or more etching process(es) that have appropriate etch selectivity to expose the contact pads 106. For example, a first dry etch process may be used to etch through the passivation layer 118, and a second dry etch process may be used to etch through the passivation layer 114. In embodiments in which the passive devices 116 are formed, the openings 122 can be patterned around the passive devices 116, such that the openings 122 are disposed between adjacent passive devices 116.

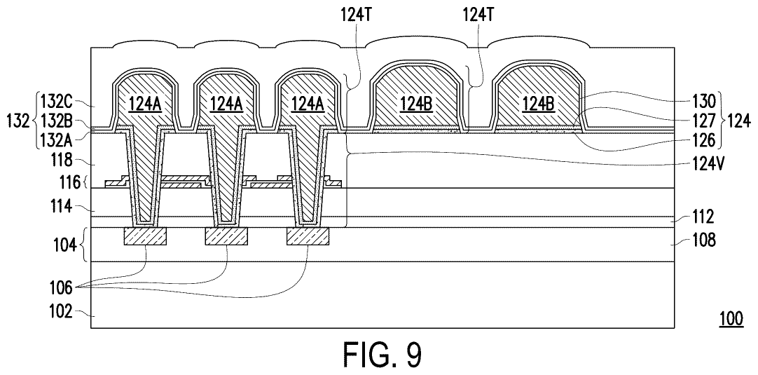

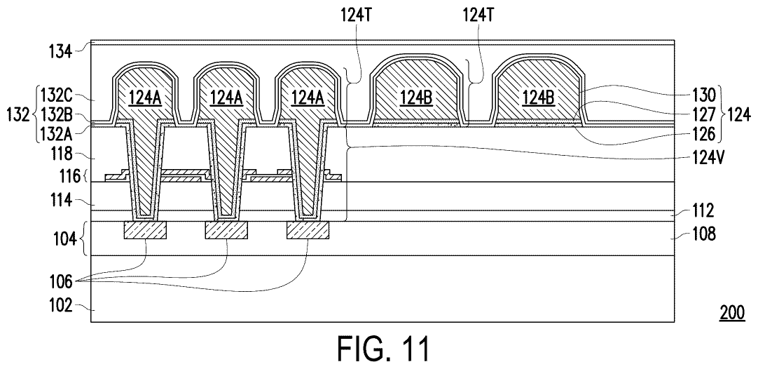

FIGS. 6 through 8 illustrate several steps in the formation of redistribution lines 124 (see FIG. 8). The redistribution lines 124 may be formed as described below or using any suitable method. In FIG. 6, a seed layer 127 may be formed over the upper surface of the passivation layer 118 and in the openings 122 (e.g., over the contact pads 106). Optionally, a liner layer 126 may be formed over the passivation layer 118 before forming the seed layer 127. The liner layer 126 may be a diffusion barrier layer, an adhesion layer, or the like. For example, the liner layer 126 may be formed along the upper surface of the passivation layer 118 and in the openings 122 along sidewalls of the passivation layer 118 and the passivation layer 114, exposed surfaces of the etch stop layer 112, and exposed upper surfaces of the contact pads 106. The liner layer 126 may include titanium, titanium nitride, tantalum, tantalum nitride, or the like. In some embodiments, the seed layer 127 is a metal layer, which may be a single layer or a composite layer including a plurality of sub-layers formed of different materials. For example, the seed layer 127 may include a copper layer over the liner layer 126 (e.g., a titanium layer). The seed layer 127 may be formed using, for example, physical vapor deposition (PVD) or the like.

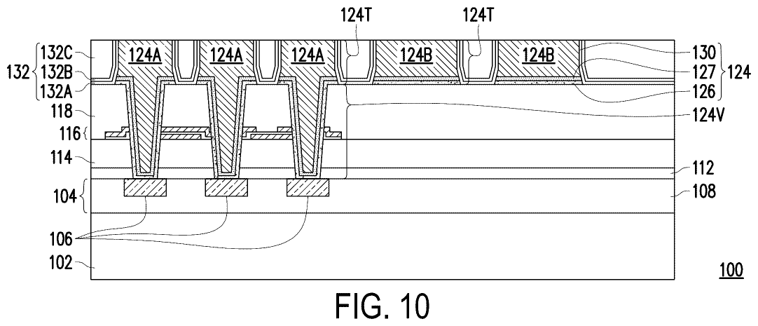

In FIG. 7, a photoresist 128 is formed and patterned on the liner layer 126 and the seed layer 127, similarly as described above in connection with the photoresist 120. The photoresist 128 may be formed by spin coating or the like and may be exposed to light for patterning. The pattern of the photoresist 128 corresponds to the redistribution lines 124 that will be subsequently formed (see FIG. 8). The patterning forms openings 129 through the photoresist 128 to expose the seed layer 127. As illustrated, some of the openings 129A may expose portions of the seed layer 127 above the contact pads 106, and some of the openings 129B may expose portions of the seed layer 126 extending parallel to the upper surface of the passivation layer 118. The openings 129B may be the locations of the redistribution lines 124 that connect to contact pads outside of the illustrated cross-section, or the openings 129B may be the locations of dummy redistribution lines 124B. For example, the dummy redistribution lines 124B assist in achieving benefits relating to pattern density (e.g., consistency of pattern density) and/or subsequent bonding of the integrated circuit die 100 to another component.

In FIG. 8, a conductive material 130 is then formed in the openings 129 of the photoresist 128 and on the exposed portions of the seed layer 127. The conductive material 130 may be formed by plating, such as by electroplating, electroless plating, or the like. The conductive material 130 may include a metal, such as copper, silver, cobalt, titanium, tungsten, aluminum, combinations thereof, or the like. For example, the conductive material 130 may be copper, a copper-silver alloy, or a copper-cobalt alloy, plated using the seed layer 127. Then, the photoresist 128 and portions of the seed layer 127 and the liner layer 126 (if present) on which the conductive material 130 are not formed are removed. The photoresist 128 may be removed by an acceptable ashing or stripping process, such as using an oxygen plasma or the like. Once the photoresist 128 is removed, exposed portions of the seed layer 127 are removed followed by portions of the liner layer 126 using one or more acceptable etching processes. An anneal process may optionally be performed. The remaining portions of the seed layer 127 and conductive material 130 (and the liner layer 126, if present) form the redistribution lines 124.

The redistribution lines 124 have trace portions 124T on and extending along the top surface of the passivation layer 118. For example, the trace portions 124T are conductive lines that extend lengthwise parallel to a major surface of the semiconductor substrate 102. Thus, the redistribution lines 124 extend along the semiconductor substrate 102 in respective lengthwise directions. A trace portion 124T of a redistribution line 124 has a length (in its lengthwise direction) and a width (in a direction perpendicular to the lengthwise direction), where the length is greater than the width. The redistribution lines 124 may also have one or more via portions 124V in respective ones of the openings 122 (through the passivation layer 118, the passivation layer 114, and the etch stop layer 112) that are physically and electrically coupled to the contact pads 106. The redistribution lines 124 (e.g., the redistribution lines 124A) may physically contact the contact pads 106. Some of the via portions 124V may be used to electrically couple the passive devices 116 to the devices of the semiconductor substrate 102.

The redistribution lines 124 may have any type of top surfaces, given the application of the integrated circuit die to be formed. In the illustrated embodiment, the redistribution lines 124 have convex top surfaces, which may be formed when lifting off a tool used during deposition of the conductive material 130. In another embodiment, the redistribution lines 124 can have flat top surfaces, concave top surfaces, polygonal top surfaces, or the like. Additionally, the trace portions 124T may have any type of sidewalls, given the application of the integrated circuit die 100 to be formed. In the illustrated embodiment, the trace portions 124T have sidewalls that are spaced apart by a tapering width that decreases in a direction extending away from the semiconductor substrate 102. In another embodiment, the trace portions 124T have substantially vertical sidewalls that are spaced apart by a constant width.

Moreover, in some cross-sectional views, the redistribution lines 124 include redistribution lines 124A comprising both a trace portion 124T and a via portion 124V as well as redistribution lines 124B comprising only a trace portion 124T disposed over an upper surface of the passivation layer 118. In some embodiments, the trace portion 124T of the redistribution lines 124B may have a greater height above the upper surface of the passivation layer 118 as compared to a height of the trace portion 124T of the redistribution lines 124A above the upper surface of the passivation layer 118. In other embodiments, the trace portions 124T of both redistribution lines 124A/124B may have substantially similar heights. Further, the trace portions 124T of the redistribution lines 124B may be longer and wider than the analogous dimensions of the trace portions 124T of the redistribution lines 124A.

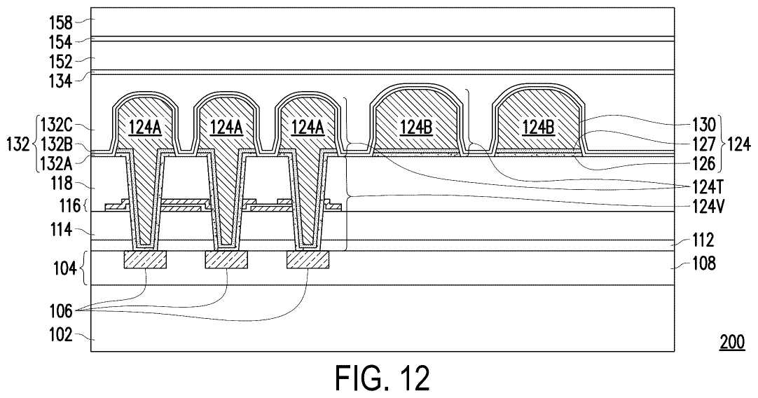

In FIG. 9, a passivation layer 132 is formed over the redistribution lines 124 and the passivation layer 118. The passivation layer 132 may be formed of one or more acceptable dielectric materials, such as silicon nitride, silicon oxide, combinations thereof, or the like. In accordance with some embodiments, the passivation layer 132 includes a nitride layer 132A, an oxide layer 132B, and a bulk oxide layer 132C. Other acceptable dielectric materials include polymers such as polyimide, solder resist, polybenzoxazole (PBO), a benzocyclobutene (BCB) based polymer, molding compound, or the like. Each of the layers of the passivation layer 132 may be formed by deposition (e.g., CVD), spin coating, lamination, combinations thereof, or the like.

For example, the nitride layer 132A may comprise silicon nitride and be formed by a CVD process. In addition, the oxide layer 132B may comprise silicon oxide, such as undoped silicate glass (USG), and be formed by a CVD process. In some embodiments, each of the nitride layer 132A and the oxide layer 132B are conformally deposited such that they substantially follow the curvature of the redistribution lines 124 and the upper surface of the passivation layer 118. Further, the bulk oxide layer 132C may be formed by a spin coating process and, optionally, followed by another USG deposition.

The passivation layer 132 may be formed to a large enough initial thickness to cover the trace portions 124T of the redistribution lines 124. In addition, an upper surface of the passivation layer 132 may have a low degree of planarity above the passivation layer 118 and the redistribution lines 124.

In FIG. 10, after depositing the passivation layer 132, the passivation layer 132 is planarized, such as by a CMP process. During the planarization process, an upper surface of the passivation layer 132 (e.g., the bulk oxide layer 132C) is decreased to expose the oxide layer 132B, then the nitride layer 132A, then the trace portions 124T of the redistribution lines 124B, and then the trace portions 124T of the redistribution lines 124A (e.g., in embodiments in which the trace portions 124T of the redistribution lines 124B have a greater height).

As illustrated, the planarization process may continue in order to remove upper portions of the redistribution lines 124. As discussed above, the upper portions of the redistribution lines 124 may have low planarities (e.g., curved upper surfaces), and the planarization process may continue until the trace portions 124T of the redistribution lines 124 are level with their corresponding sidewalls. As a result, the redistribution lines 124 may be level with the passivation layer 132 (e.g., the bulk oxide layer 132C and sidewall portions of the nitride layer 132A and the oxide layer 132B). In addition, remaining portions of the passivation layer 132 remain disposed between trace portions 124T of adjacent redistribution lines 124.

In accordance with various embodiments, the integrated circuit die 100 may be attached in a die structure (and subsequently incorporated into a semiconductor package). Before attachment, the integrated circuit die 100 may be singulated or remain in wafer form. The integrated circuit die 100 may serve as a bottom die or a top die within the die structure. As discussed in greater detail below, the trace portions 124T of the redistribution lines 124 may be utilized for direct bonding.

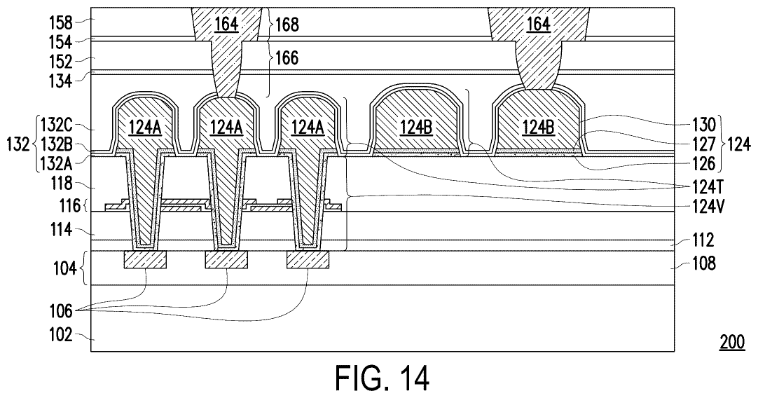

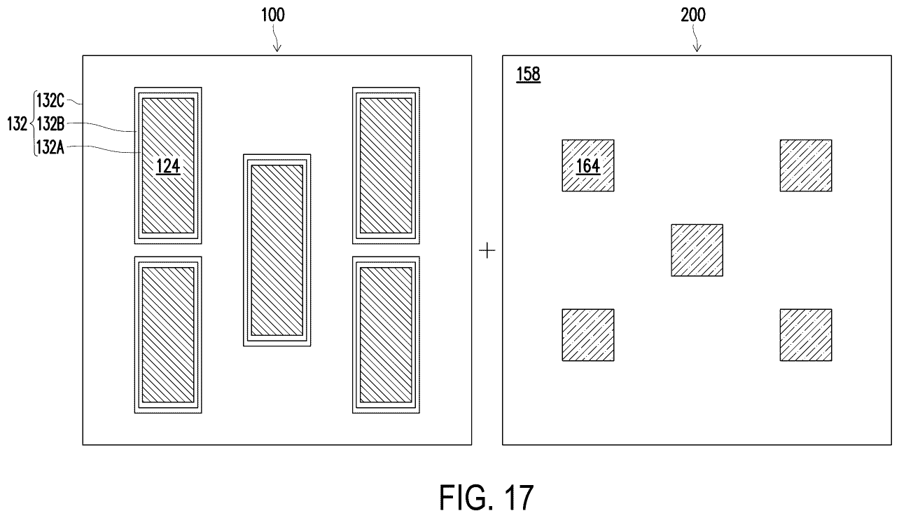

FIGS. 11 through 14 are cross-sectional views of intermediate stages in the manufacturing of an integrated circuit die 200 (see FIG. 14), in accordance with some embodiments. The integrated circuit die 200 may be a logic device (e.g., CPU, GPU, microcontroller, etc.), a memory device (e.g., DRAM die, SRAM die, etc.), a power management device (e.g., PMIC die), an RF device, a sensor device, a MEMS device, a signal processing device (e.g., DSP die), a front-end device (e.g., AFE die), the like, or combinations thereof (e.g., an SoC die). The integrated circuit die 200 may be formed in a wafer, which may include different device regions that are singulated in subsequent steps to form a plurality of integrated circuit dies 200.

As discussed in greater detail below, the integrated circuit die 200 may subsequently be bonded to the integrated circuit die 100 (see FIGS. 10 and 15-18D). The integrated circuit die 200 is formed similarly as described above in connection with the integrated circuit die 100 (see FIGS. 1 through 10), unless stated otherwise below. Note that like numbers indicate like features between the integrated circuit dies 100/200. In accordance with various embodiments, processing of the integrated circuit die 200 may differ from processing of the integrated circuit die 100 after following formation of the passivation layer 132 over the redistribution lines 124 (see FIG. 9).

In FIG. 11, after forming the structure of FIG. 9, the passivation layer 132 may be planarized, such as by a CMP process, similarly as described above in connection with FIG. 10 but with certain differences. For example, the planarization process is performed on the bulk oxide layer 132C and is completed before reaching the oxide layer 132B, the nitride layer 132A, or the redistribution lines 124. As a result of planarization, the upper surface of the passivation layer 132 may have a high degree of planarity.

Although the thickness of the passivation layer 132 decreases during the planarization process, a remaining portion of the passivation layer 132 covers the redistribution lines 124 after the planarization process is complete. Thus, after being planarized, the passivation layer 132 of the integrated circuit die 200 may have a greater thickness than the passivation layer 132 of the integrated circuit die 100 (see FIG. 10). The planar upper surface of the passivation layer 132 extends continuously over the redistribution lines 124 and within the areas between the redistribution lines 124. The entirety of each respective area between the trace portions 124T of the redistribution lines 124 may be filled by the passivation layer 132. The redistribution lines 124 are spaced apart from the subsequently formed passive devices by the portions of the passivation layer 132 over the redistribution lines 124.

After the planarization process, an etch stop layer 134 may be formed on the passivation layer 132. The etch stop layer 134 will be located between the passivation layer 132 and a subsequently formed overlying passivation layer. The etch stop layer 134 may be formed of a dielectric material having a high etching selectivity from the etching of the overlying passivation layer, such as silicon nitride, silicon oxynitride, or the like, which may be formed by any suitable deposition process, such as CVD, ALD, or the like.

Optionally, passive devices (not specifically illustrated) are formed on the etch stop layer 134. The passive devices may include capacitors, inductors, resistors, and the like. The passive devices are embedded passive devices, and may be electrically coupled to the devices of the semiconductor substrate 102. The passive devices may be formed similarly as described above in connection with the passive devices 116. In some embodiments, one or more of the passive devices may have a metal-insulator-metal (MIM) structure that includes one or more metal layer(s) and one or more insulating layer(s). The integrated circuit die 100 may include any desired combination and quantity of these passive devices.

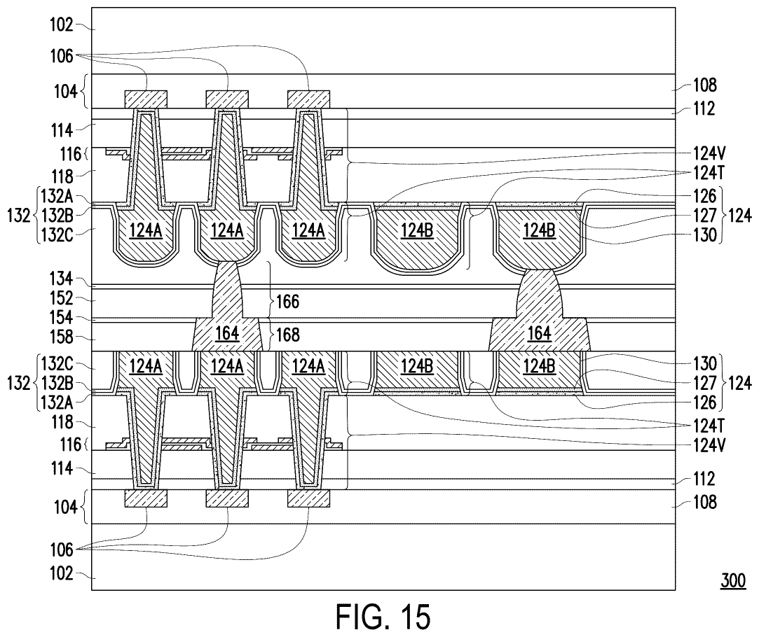

In FIG. 12, a dielectric layer 152 is formed over the etch stop layer 134 (and over the passive devices, if present). The dielectric layer 152 may be formed of an oxide such as silicon oxide, phosphosilicate glass (PSG), borosilicate glass (BSG), boron-doped phosphosilicate glass (BPSG), a tetraethyl orthosilicate (TEOS) based oxide (e.g., low temperature TEOS), or the like; a nitride such as silicon nitride or the like; a combination thereof; or the like. The dielectric layer 152 may be formed, for example, by CVD, ALD, or the like. For example, the dielectric layer 152 may be formed of silicon oxide deposited using TEOS. The dielectric material of the dielectric layer 152 may be different than the dielectric material of the passivation layer 132. For example, the dielectric layer 152 may be formed of silicon oxide while the passivation layer 132 may be formed of silicon nitride. Similar to the passivation layer 132, the dielectric layer 152 may be thick and flat, which may provide a large space on which passive devices may be formed in subsequent processing.

An etch stop layer 154 may be formed on the dielectric layer 152. The etch stop layer 154 will be located between the dielectric layer 152 and a subsequently formed overlying dielectric layer. The etch stop layer 154 may be formed of a dielectric material having a high etching selectivity from the etching of the overlying passivation layer, such as silicon nitride (e.g., low temperature silicon nitride), silicon oxynitride, or the like, which may be formed by any suitable deposition process, such as CVD, ALD, or the like.

Optionally, passive devices (not specifically illustrated) are formed on the etch stop layer 154, similarly as described above. The passive devices 156 may include capacitors, inductors, resistors, and the like. The passive devices 156 are embedded passive devices, and may be electrically coupled to the devices of the semiconductor substrate 102. The passive devices may be any of those previously described. The integrated circuit die 100 may include any desired combination and quantity of these passive devices. As previously described in greater detail, one or more of the passive devices may have a MIM structure that includes one or more metal layer(s) and insulating layer(s).

Further, a dielectric layer 158 may be formed over the etch stop layer 154 (and over the passive devices, if present). The dielectric layer 158 may be formed of an oxide such as silicon oxide, phosphosilicate glass (PSG), borosilicate glass (BSG), boron-doped phosphosilicate glass (BPSG), a tetraethyl orthosilicate (TEOS) based oxide (e.g., low temperature TEOS), or the like; a nitride such as silicon nitride or the like; a combination thereof; or the like. The dielectric layer 158 may be formed, for example, by CVD, ALD, or the like. For example, the dielectric layer 158 may be formed of silicon oxide deposited using TEOS. The dielectric layer 158 may also be referred to as a dielectric bond layer. In some embodiments (not specifically illustrated), the dielectric layer 158 may include a capping layer of, e.g., undoped silicate glass (USG).

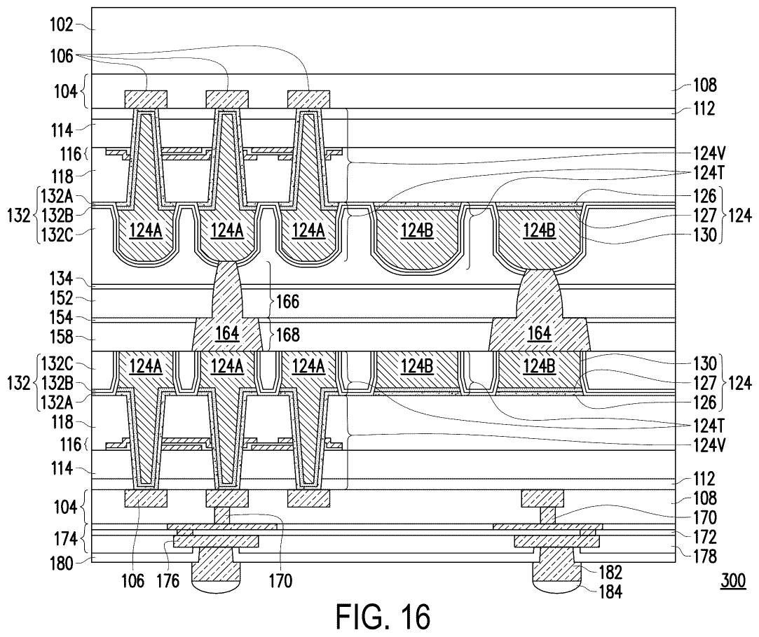

In FIG. 13, die connector openings (including via openings 160 and bond pad openings 162) are patterned in the dielectric layer 158, the etch stop layer 154, the dielectric layer 152, the etch stop layer 134, and the passivation layer 132, thereby exposing the redistribution lines 124. The die connector openings may be formed by acceptable photolithography and etching techniques.

The die connector openings may be formed by a damascene process. In this embodiment, the die connector openings are formed by a single damascene process. In a single damascene process, the bond pad openings 162 are formed through the dielectric layer 158 and the etch stop layer 154, while the via openings 160 are formed through the dielectric layer 152, the etch stop layer 134, and the passivation layer 132. The via openings 160 expose the redistribution lines 124. In another embodiment, the etch stop layer 154 and the dielectric layer 158 are omitted, and the die connector openings are formed by a dual damascene process. In a dual damascene process, the bond pad openings 162 are formed through an upper portion of the dielectric layer 152, while the via openings 160 are formed through a lower portion of the dielectric layer 152, the etch stop layer 134, and the passivation layer 132.

In FIG. 14, die connectors 164 (including vias 166 and bond pads 168) are formed in the die connector openings (including, respectively, the via openings 160 and the bond pad openings 162). The die connectors 164 may be formed of a suitable conductive material, such as copper, tungsten, aluminum, silver, gold, a combination thereof, or the like, which can be formed by, for example, plating or the like. The excess portions of the conductive material, which excess portions are over the top surface of the dielectric layer 158, are then removed. In some embodiments, a planarization process such as a chemical mechanical polish (CMP), an etch-back process, combinations thereof, or the like may be utilized. After the planarization process, the top surfaces of the die connectors 164 may be coplanar (within process variations) with the top surface of the dielectric layer 158. The die connectors 164 are physically and electrically coupled to the redistribution lines 124. The die connectors 164 may physically contact the trace portions 124T of the redistribution lines 124. Some of the die connectors 164 (e.g., the vias 166) may be used to electrically couple the passive devices 136, 156 to the devices of the semiconductor substrate 102.

The bond pads 168 of the die connectors 164 are disposed in the dielectric layer 158, while the vias 166 of the die connectors 164 are disposed in the dielectric layer 152 and the passivation layer 132. The vias 166 extend through the portions of the passivation layer 132 that are over the redistribution lines 124.

As discussed above, the integrated circuit die 200 may be bonded to the integrated circuit die 100 to form a die structure (and subsequently incorporated into a semiconductor package). Similarly as described above in connection with the integrated circuit die 100, the integrated circuit die 200 may be singulated or remain in wafer form. The integrated circuit die 200 may serve as a bottom die or a top die. As discussed in greater detail below, the bond pads 168 of the integrated circuit die 200 may be directly bonded to the redistribution lines 124 of the integrated circuit die 100.

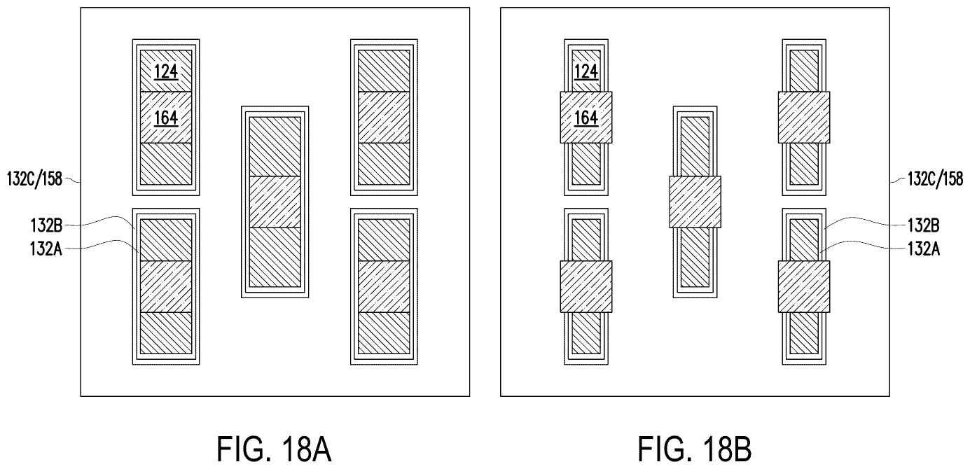

FIG. 15 is a cross-sectional view of a die structure 300, in accordance with some embodiments. The die structure 300 is a stack of integrated circuit dies (including a first integrated circuit die 100 and a second integrated circuit die 200). The die structure 300 is formed by bonding the integrated circuit dies 100/200. Some of the redistribution lines 124 (e.g., the trace portions 124T) of the first integrated circuit die 100 may be coupled (e.g., directly bonded) to some of the die connectors 164 (e.g., the bond pads 168) of the second integrated circuit die 200. In some embodiments, the first integrated circuit die 100 is in wafer form while the second integrated circuit die 200 may be singulated from its wafer before attachment to the first integrated circuit die 100, or vice versa. In additional embodiments, both of the integrated circuit dies 100/200 may remain in wafer form during attachment. In further embodiments, one or both of the integrated circuit dies 100/200 may be singulated and included into a reconstructed wafer before the attachment.

As an example of the bonding process, the second integrated circuit die 200 may be bonded to the first integrated circuit die 100 by direct bonding. For example, a bonding interface between the integrated circuit dies 100/200 may include metal-to-metal bonding and dielectric-to-dielectric bonding. In addition, some portions of the bonding interface may be metal-to-dielectric. In accordance with various embodiments, the dielectric layer 158 of the second integrated circuit die 200 is directly bonded to the passivation layer 132 of the first integrated circuit die 100 through dielectric-to-dielectric bonding, without using any adhesive material (e.g., die attach film). The die connectors 164 of the second integrated circuit die 200 are directly bonded to the redistribution lines 124 of the first integrated circuit die 100 through metal-to-metal bonding, without using any eutectic material (e.g., solder).

The bonding may include a pre-bonding and an annealing. During the pre-bonding, a small pressing force is applied to press the second integrated circuit die 200 against the first integrated circuit die 100. The pre-bonding is performed at a low temperature, such as about room temperature, and after the pre-bonding, the dielectric layer 158 of the second integrated circuit die 200 is bonded to the passivation layer 132 of the first integrated circuit die 100. The bonding strength is then improved in a subsequent annealing step, in which the passivation layer 132 and the redistribution lines 124 of the first integrated circuit die 100 and the dielectric layer 158 and the die connectors 164 of the second integrated circuit die 200 are annealed.

After the annealing, direct bonds such as fusion bonds are formed, bonding the passivation layer 132 of the first integrated circuit die 100 to the dielectric layer 158 of the second integrated circuit die 200. For example, the bonds can be covalent bonds between the material of the passivation layer 132 of the first integrated circuit die 100 and the material of the dielectric layer 158 of the second integrated circuit die 200.

In addition, the redistribution lines 124 of the first integrated circuit die 100 may be connected to the die connectors 164 of the second integrated circuit die 200 with a one-to-one correspondence or any suitable ratio. The redistribution lines 124 of the first integrated circuit die 100 and the die connectors 164 of the second integrated circuit die 200 may be in physical contact after the pre-bonding, or may expand to be brought into physical contact during the annealing. Further, during the annealing, the material of the redistribution lines 124 (e.g., copper or an alloy as described above) of the first integrated circuit die 100 and the die connectors 164 of the second integrated circuit die 200 (e.g., copper) intermingles, so that metal-to-metal bonds are also formed.

As a result, the bonding interface includes both dielectric-to-dielectric bonds and metal-to-metal bonds. The dielectric-to-dielectric bonds may include oxide-to-oxide bonds (e.g., O—Si—O), nitride-to-nitride bonds (e.g., N—Si—N), and oxide-to-nitride bonds (e.g., O—Si—N). This variety of bonding is due to the dielectric layer 158 (e.g., comprising an oxide and/or a nitride) being bonded to portions of the bulk oxide layer 132C and, in some cases, portions of the nitride layer 132A and the oxide layer 132B. Collectively, the redistribution lines 124, the passivation layer 132, the die connectors 164, and the dielectric layer 158 may be referred to as a bonding region.

Metal-to-dielectric regions of the bonding interface may include portions of the redistribution lines 124 of the first integrated circuit die 100 being in physical contact with the dielectric layer 158 of the second integrated circuit die 200. The quantity and proportion of these interface regions may be prevalent due to the redistribution lines 124 composing a greater fraction than the die connectors 164 of the bonding interface. In some embodiments, the metal-to-dielectric interface regions may comprise chemical bonds between, e.g., metal atoms of the redistribution lines 124 and oxygen and/or nitrogen atoms of the dielectric layer 158. Similarly, some of the die connectors 164 may overlap the passivation layer 132, thereby forming analogous metal-to-dielectric interface regions.

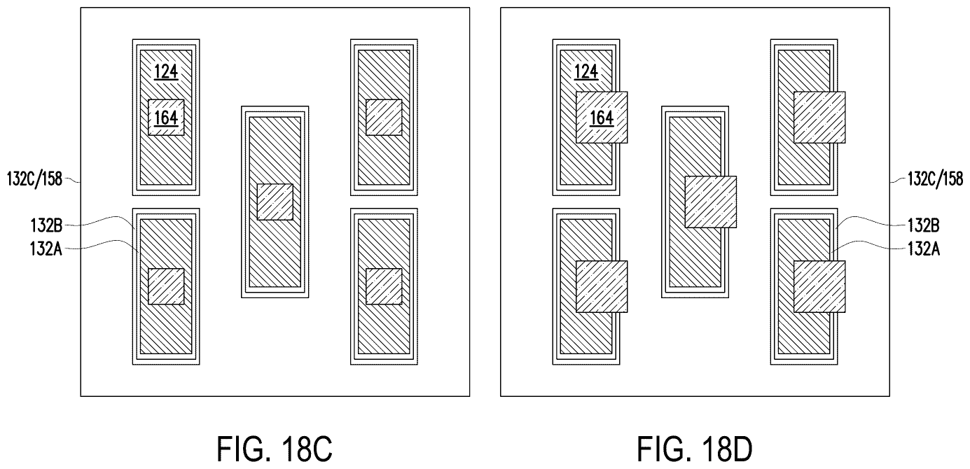

FIG. 16 illustrates further processing that the die structure 300 may undergo in preparation for incorporating the die structure 300 into a semiconductor package. For example, one of the semiconductor substrates 102 may be thinned or removed, and through vias 170 are formed or exposed (if already present). As illustrated, the through vias 170 may be electrically connected to the device layer and/or interconnect structure 104. In some embodiments, dielectric layers 172 and redistribution lines 174 are formed over the through vias 170. The redistribution lines 174 may include metal pads 176, and one or more passivation layers 178 may be formed over the metal pads 178.

As illustrated, conduct connectors are formed over the metal pads 178. For example, openings may be formed through the passivation layers 178 to expose the metal pads 176, and a dielectric material 180 may be formed over the passivation layers 178 and the metal pads 178. The dielectric material 180 may include nitrides or polymers such as polyimide, solder resist, polybenzoxazole (PBO), a benzocyclobutene (BCB) based polymer, molding compound, or the like. Openings are then formed through the dielectric material 180 to re-expose the metal pads 178, and conductive connectors are then formed over the exposed metal pads 178. In some embodiments, the conductive connectors include under-bump metallurgies (UBMs) 182 with solder bumps 184 formed thereon. The die structure 300 may then be singulated from the wafer and attached to a carrier substrate or otherwise incorporated into a semiconductor package.

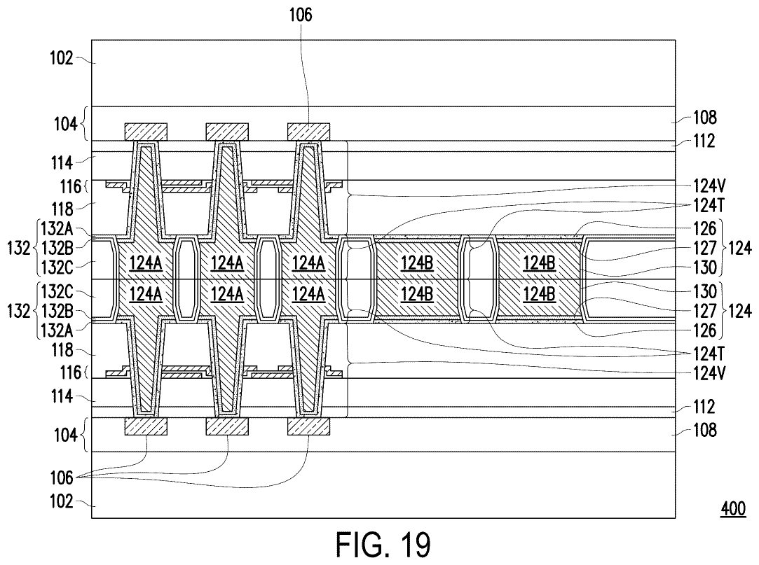

FIG. 17 illustrates plan views (e.g., top down layout views) of the first integrated circuit die 100 and the second integrated circuit die 200 of the die structure 300, in accordance with some embodiments. In particular, the bonding faces of the integrated circuit dies 100/200 are shown. The bonding face of the first integrated circuit die 100 includes the redistribution lines 124 (e.g., the trace portions 124T), which are embedded in the passivation layer 132 (e.g., the nitride layer 132A, the oxide layer 132B, and the bulk oxide layer 132C). The bonding face of the second integrated circuit die 200 includes the die connectors 164 (e.g., the bond pads 168), which are embedded in the dielectric layer 158. Although the redistribution lines 124 are illustrated as having rectangular shapes, the redistribution lines 124 may have any suitable shapes, such as being oval or rounded rectangles. Because the redistribution lines 124 include electrically connected redistribution lines 124A, some of the trace portions 124T will have shapes and patterns of traces in a circuit, while the dummy redistribution lines 124B may have the above described shapes or trace patterns as well. Similarly, although the die connectors 164 are illustrated as having square shapes, the die connectors 164 may have any suitable shapes, such as being circular or rounded squares. In some embodiments, a width of the redistribution lines 124 substantially the same as a width (e.g., side length or diameter) of the die connectors 164. However, lengths of the redistribution lines 124 may be greater than these other dimensions.

In some embodiments, the bonding face of the first integrated circuit die 100 may have a redistribution line 124 pattern density ranging from 50% to 80%. As discussed above, the redistribution lines 124 and the die connectors 164 may have a one-to-one correspondence. In some embodiments, more than one die connector 164 may correspond to some or all of the redistribution lines 124. For example, one or more of the redistribution lines 124 may be bonded to two or more die connectors 164.

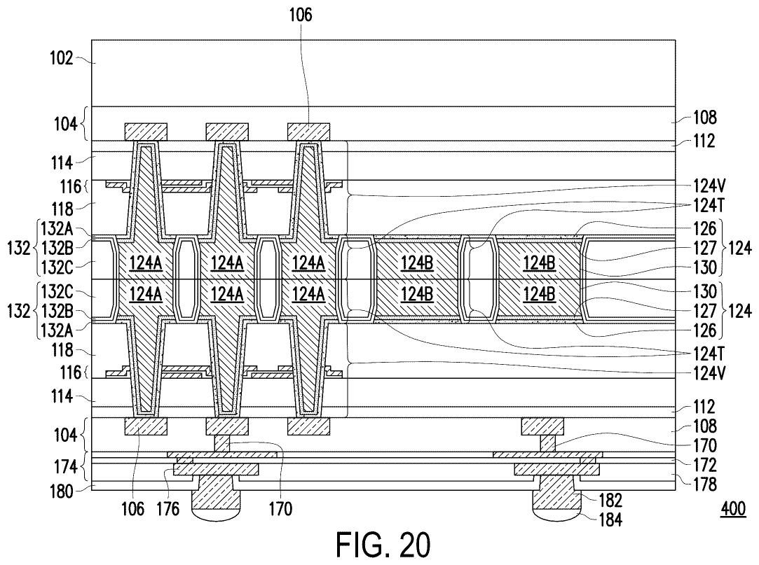

FIGS. 18A through 18D illustrate exemplary bonding interface layouts after attaching the integrated circuit dies 100/200 to one another. The embodiments described above may be applicable to these exemplary layouts. In addition, embodiment die structures 300 may include one or more of the provided layouts in any suitable combination.

FIG. 18A provides an exemplary layout in which the die connectors 164 have a width (or a diameter) that is substantially the same as a width of the redistribution lines 124. As a result, substantially all of a surface of the die connector 164 may be in physical contact with a surface of the corresponding redistribution line 124. In addition, remaining portions of the surface of the redistribution line 124 may be in physical contact with the dielectric layer 158.

FIG. 18B provides an exemplary layout in which the die connectors 164 have a width that is greater than a width of the redistribution lines 124. As a result, the die connector 164 may overextend one or more edges of the corresponding redistribution line 124 and be in physical contact with any number of the passivation layers 132. In addition, remaining portions of the surface of the redistribution line 124 may be in physical contact with the dielectric layer 158, similarly as described above.

FIG. 18C provides an exemplary layout in which the die connectors 164 have a width that is lesser than a width of the redistribution lines 124. As a result, the redistribution line 124 may overextend all edges of the corresponding die connector 164. In addition, remaining portions of the surface of the redistribution line 124 being in physical contact with the dielectric layer 158 may be greater than the analogous remaining portions described in connection with FIG. 18A.

FIG. 18D provides an exemplary layout in which the die connectors 164 are misaligned with the redistribution lines 124. The die connectors 164 and the redistribution lines 124 may have any of the relative dimensions described above in connection with FIGS. 18A through 18C. As a result, the die connector 164 and the corresponding redistribution line 124 may overextend one another, similarly as described above in connection with FIG. 18C. Accordingly, the die connector 164 may be in physical contact with any number of the passivation layers 132, and the redistribution line 124 may be in physical contact with the dielectric layer 158.

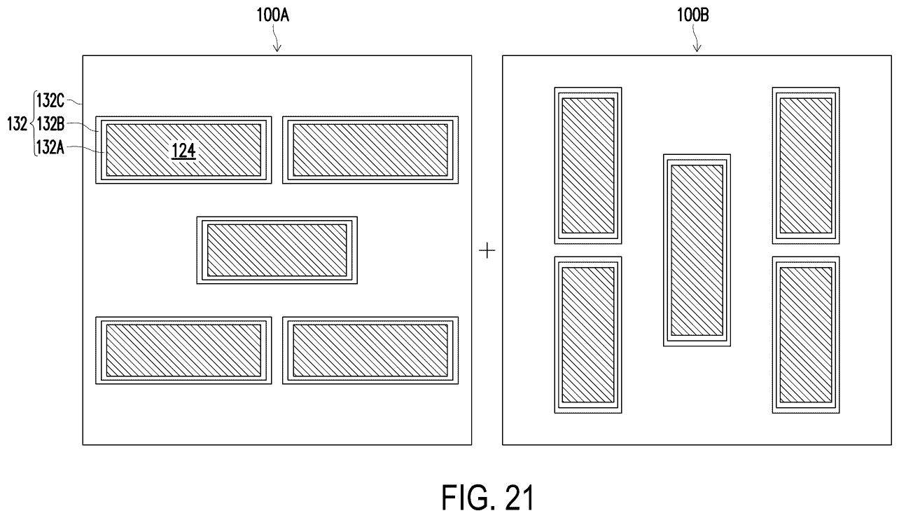

FIG. 19 is a cross-sectional view of a die structure 400, in accordance with some embodiments. The die structure 400 is a stack of integrated circuit dies (including a first integrated circuit die 100A and a second integrated circuit die 100B). The die structure 400 is formed by bonding the integrated circuit dies 100 to one another. Some of the redistribution lines 124 (e.g., the trace portions 124T) of the first integrated circuit die 100A may be coupled (e.g., directly bonded) to some of the redistribution lines 124 (e.g., the trace portions 124T) of the second integrated circuit die 100B. In some embodiments, the first integrated circuit die 100A is in wafer form while the second integrated circuit die 100A may be singulated from its wafer before attachment to the first integrated circuit die 100A, or vice versa. In additional embodiments, both of the integrated circuit dies 100 may remain in wafer form during attachment. In further embodiments, one or both of the integrated circuit dies 100 may be singulated and included into a reconstructed wafer before the attachment.

As an example of the bonding process, the second integrated circuit die 100B may be bonded to the first integrated circuit die 100A by direct bonding. For example, a bonding interface between the integrated circuit dies 100 may include metal-to-metal bonding and dielectric-to-dielectric bonding. In addition, some portions of the bonding interface may be metal-to-dielectric. In accordance with various embodiments, the passivation layer 132 of the second integrated circuit die 100B is directly bonded to the passivation layer 132 of the first integrated circuit die 100A through dielectric-to-dielectric bonding, without using any adhesive material (e.g., die attach film). The redistribution lines 124 of the second integrated circuit die 100B are directly bonded to the redistribution lines 124 of the first integrated circuit die 100A through metal-to-metal bonding, without using any eutectic material (e.g., solder).

The bonding may include a pre-bonding and an annealing. During the pre-bonding, a small pressing force is applied to press the second integrated circuit die 100B against the first integrated circuit die 100A. The pre-bonding is performed at a low temperature, such as about room temperature, and after the pre-bonding, the passivation layer 132 of the second integrated circuit die 100B is bonded to the passivation layer 132 of the first integrated circuit die 100A. The bonding strength is then improved in a subsequent annealing step, in which the passivation layer 132 and the redistribution lines 124 of the first integrated circuit die 100A and the passivation layer 132 and the redistribution lines 124 of the second integrated circuit die 100B are annealed.

After the annealing, direct bonds such as fusion bonds are formed, bonding the passivation layer 132 of the first integrated circuit die 100A to the passivation layer 132 of the second integrated circuit die 100B. For example, the bonds can be covalent bonds between the material(s) of the respective passivation layers 132, which may include same, similar, or different layers.

In addition, the redistribution lines 124 of the first integrated circuit die 100A may be connected to the redistribution lines 124 of the second integrated circuit die 100B with a one-to-one correspondence or any suitable ratio. The respective redistribution lines 124 of the integrated circuit dies 100 may be in physical contact after the pre-bonding, or may expand to be brought into physical contact during the annealing. Further, during the annealing, the material(s) of the respective redistribution lines 124 (e.g., copper or an alloy as described above) intermingles, so that metal-to-metal bonds are also formed. Note that the respective redistribution lines 124 may include same, similar, or different materials.

As a result, the bonding interface includes both dielectric-to-dielectric bonds and metal-to-metal bonds. The dielectric-to-dielectric bonds may include oxide-to-oxide bonds (e.g., O—Si—O), nitride-to-nitride bonds (e.g., N—Si—N), and oxide-to-nitride bonds (e.g., O—Si—N). This variety of bonding is due to the respective passivation layers 132 comprising oxide and nitride layers being bonded to one another. This variety of bonding is also due to the respective redistribution lines 124 having different sizes and shapes and/or being misaligned with one another. Collectively, the redistribution lines 124, the passivation layer 132, the die connectors 164, and the dielectric layer 158 may be referred to as a bonding region.

Metal-to-dielectric regions of the bonding interface may include portions of the redistribution lines 124 of the first integrated circuit die 100A being in physical contact with the passivation layer 132 of the second integrated circuit die 100A as well as portions of the redistribution lines 124 of the second integrated circuit die 100B being in physical contact with the passivation layer 132 of the first integrated circuit die 100A. The quantity and proportion of these interface regions is dependent on the degree to which the respective redistribution lines 124 differ in size, shape, and/or alignment. In some embodiments, the metal-to-dielectric interface regions may comprise chemical bonds between, e.g., metal atoms of the redistribution lines 124 of one of the integrated circuit dies 100 and oxygen and/or nitrogen atoms of the corresponding passivation layer 132 of the other of the integrated circuit dies 100.

FIG. 20 illustrates further processing that the die structure 400 may undergo in preparation for incorporating the die structure 400 into a semiconductor package. For example, one of the semiconductor substrates 102 may be thinned or removed, and through vias 170 are formed or exposed (if already present). As illustrated, the through vias 170 may be electrically connected to the device layer and/or interconnect structure 104. In some embodiments, dielectric layers 172 and redistribution lines 174 are formed over the through vias 170. The redistribution lines 174 may include metal pads 176, and one or more passivation layers 178 may be formed over the metal pads 178.

As illustrated, conduct connectors are formed over the metal pads 178. For example, openings may be formed through the passivation layers 178 to expose the metal pads 176, and a dielectric material 180 may be formed over the passivation layers 178 and the metal pads 178. The dielectric material 180 may include nitrides or polymers such as polyimide, solder resist, polybenzoxazole (PBO), a benzocyclobutene (BCB) based polymer, molding compound, or the like. Openings are then formed through the dielectric material 180 to re-expose the metal pads 178, and conductive connectors are then formed over the exposed metal pads 178. In some embodiments, the conductive connectors include under-bump metallurgies (UBMs) 182 with solder bumps 184 formed thereon. The die structure 400 may then be singulated from the wafer and attached to a carrier substrate or otherwise incorporated into a semiconductor package.

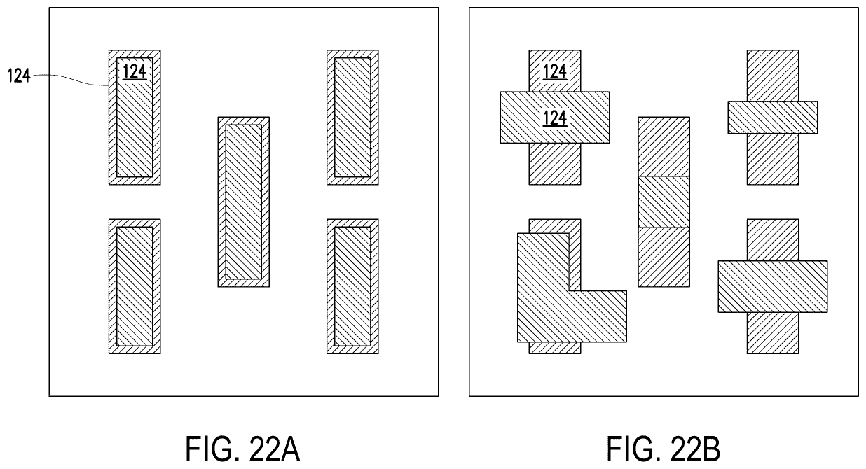

FIG. 21 illustrates plan views (e.g., top down layout views) of the first integrated circuit die 100A and the second integrated circuit die 100A of the die structure 400, in accordance with some embodiments. In particular, the bonding faces of the integrated circuit dies 100 are shown. Both of the bonding faces of the integrated circuit dies 100 include the redistribution lines 124 (e.g., the trace portions 124T), which are embedded in the passivation layer 132 (e.g., the nitride layer 132A, the oxide layer 132B, and the bulk oxide layer 132C). Although the plan views illustrate the redistribution lines 124 as having rectangular shapes, these features may have any suitable shapes such as those discussed above in connection with the die structure 300.

In some embodiments, the bonding faces of each of the integrated circuit dies 100 may have a redistribution line 124 pattern density ranging from 50% to 80%. In particular, the bonding face of the first integrated circuit die 100A may have a greater pattern density than the second integrated circuit die 100B, or vice versa. The integrated circuit dies 100 may have a substantially same pattern density or differ within the limits of the above-described range. As discussed above, the respective redistribution lines 124 of the integrated circuit dies 100 may have a one-to-one correspondence. In some embodiments, any particular redistribution line 124 of the integrated circuit dies 100 may be bonded to more than one redistribution lines 124 of the other integrated circuit die 100. As such, the bonding interface may include any variety of the above, while the integrated circuit dies 100 have a substantially one-to-one correspondence or otherwise.

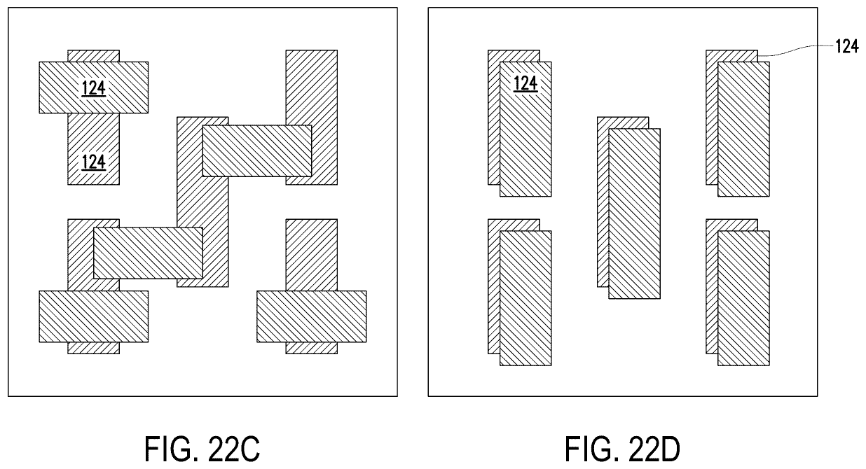

FIGS. 22A through 22D illustrate exemplary bonding interface layouts after attaching the integrated circuit dies 100 to one another. The embodiments described may be applicable to these exemplary layouts. In addition, embodiment die structures 400 may include one or more of the provided layouts in any suitable combination.

FIG. 22A provides an exemplary layout in which the corresponding redistribution lines 124 have substantially same shapes, sizes, and patterns. As a result, substantially all of surfaces of the corresponding redistribution lines 124 may be in physical contact with one another. Similarly, substantially all of surfaces of the corresponding passivation layers 132 may be in physical contact with one another.

FIG. 22B provides an exemplary layout in which the corresponding redistribution lines 124 have a different shape, size, and/or pattern (e.g., orientation). As a result, the redistribution lines 124 may overextend one another and be in physical contact with any number of the passivation layers 132 of the other integrated circuit die 100.

FIG. 22C provides an exemplary layout in which some of the redistribution lines 124 of either integrated circuit die 100 are directly bonded to more than one corresponding redistribution line 124 of the other integrated circuit die 100. As a result, these redistribution lines 124 will overextend one another and be in physical contact with some or all of the passivation layers 132 of the other integrated circuit die 100, similarly as described in connection with FIG. 22B.

FIG. 22D provides an exemplary layout in which the corresponding redistribution lines 124 are misaligned with one another. The redistribution lines 124 may have any of the relative dimensions described above in connection with FIGS. 22A through 22C. As a result, the corresponding redistribution lines 124 may overextend one another, similarly as described above in connection with FIGS. 22B and 22C. Accordingly, the redistribution lines 124 may be in physical contact with any number of the passivation layers 132 of the other integrated circuit die 100.

Embodiments may achieve advantages. In particular, the disclosed embodiments provide integrated circuit dies 100 that may be fabricated with fewer steps and having a lesser thickness due to using the redistribution lines 124 for direct bonding. In addition, die structures 300/400 that include one or more integrated circuit dies 100 may also be assembled to have a lesser thickness. Further, the pattern density of the redistribution lines 124 may be greater than the pattern density of die connectors 164 (e.g., bond pads 168).

In an embodiment, a method includes forming active devices over a semiconductor substrate; forming an interconnect structure over the semiconductor substrate, the interconnect structure comprising a contact pad embedded in a dielectric layer; forming a first passivation layer over the interconnect structure; forming a first opening through the first passivation layer to expose the contact pad; depositing a seed layer over the first passivation layer and in the first opening; forming a sacrificial material over the seed layer; patterning the sacrificial material to reform the first opening and to form a second opening; depositing conductive material to form a first redistribution line in the first opening and a second redistribution line in the second opening; removing the sacrificial material; and attaching an integrated circuit die to the first redistribution line and the second redistribution line. In another embodiment, the method further includes, after removing the sacrificial material, forming a second passivation layer over the first redistribution line and the second redistribution line; and planarizing the second passivation layer to be level with the first redistribution line and the second redistribution line. In another embodiment, planarizing the second passivation layer comprises removing an upper portions of the first redistribution line and the second redistribution line. In another embodiment, the second passivation layer comprises: a nitride layer along the first passivation layer, the first redistribution line, and the second redistribution line; an oxide layer over the nitride layer; and a bulk oxide layer over the oxide layer. In another embodiment, after planarizing the second passivation layer comprises leveling upper surfaces of the first redistribution line and the second redistribution line with upper surfaces of the nitride layer, the oxide layer, and the bulk oxide layer. In another embodiment, attaching the integrated circuit die comprises: direct bonding a first die connector of the integrated circuit die to the first redistribution line; and direct bonding a second die connector of the integrated circuit die to the second redistribution line. In another embodiment, attaching the integrated circuit die comprises direct bonding a third redistribution line of the integrated circuit die to the first redistribution line and the second redistribution line. In another embodiment, the second redistribution line is a dummy redistribution line. In another embodiment, the method further includes, before depositing the seed layer, depositing a barrier layer along the first passivation layer and the contact pad.

In an embodiment, a semiconductor device includes a first integrated circuit die comprising: a first interconnect structure over a device layer, the first interconnect structure comprising a first contact pad; a first passivation layer over the first interconnect structure; a second passivation layer over the first passivation layer; and a first redistribution line extending from an upper surface of the second passivation layer to the first contact pad; and a second integrated circuit die attached to the first integrated circuit die, a conductive feature of the second integrated circuit die being direct bonded to the first redistribution line, a dielectric layer of the second integrated circuit die being direct bonded to the second passivation layer. In another embodiment, the first integrated circuit die further comprises a second redistribution line extending from the upper surface of the second passivation layer to an upper surface of the first passivation layer. In another embodiment, the conductive feature is a third redistribution line. In another embodiment, the second integrated circuit die further comprises a second interconnect structure over and electrically connected to the third redistribution line, and wherein the second interconnect structure comprises a second contact pad being in physical contact with the third redistribution line. In another embodiment, the conductive feature is a die connector comprising a bond pad and a via, and wherein the second integrated circuit die further comprises: a third redistribution line over and electrically connected to the via; a second interconnect structure over and electrically connected to the third redistribution line; and a second device layer over and electrically connected to the second interconnect structure. In another embodiment, the first passivation layer comprises a lower passivation layer and an upper passivation layer, and wherein the first integrated circuit die further comprises passive devices disposed along an interface between the lower passivation layer and the upper passivation layer.

In an embodiment, a semiconductor device includes a first integrated circuit comprising a first device layer and a first interconnect structure; a second integrated circuit electrically connected to the first integrated circuit, the second integrated circuit comprising a second device layer and a second interconnect structure; and a bonding region interposed between the first interconnect structure and the second interconnect structure, the bonding region comprising: a first passivation layer adjacent to the first interconnect structure; first redistribution lines embedded in the first passivation layer; a second passivation layer adjacent to the second interconnect structure, the second passivation layer being bonded to the first passivation layer; and second redistribution lines embedded in the second passivation layer, the second redistribution lines being bonded to the first redistribution lines. In another embodiment, the first redistribution lines comprise a first active redistribution line and a first dummy redistribution line, wherein the second redistribution lines comprise a second active redistribution line and a second dummy redistribution line, and wherein the first dummy redistribution line and the second dummy redistribution line are electrically isolated from the first integrated circuit and the second integrated circuit. In another embodiment, the first active redistribution line is direct bonded to the second active redistribution line, and wherein the first dummy redistribution line is directed bonded to the second dummy redistribution line. In another embodiment, the first redistribution lines further comprise a third active redistribution line, and wherein the third active redistribution line is direct bonded to the second active redistribution line. In another embodiment, some of the first redistribution lines are in physical contact with the second passivation layer, and wherein some of the second redistribution lines are in physical contact with the first passivation layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming active devices over a semiconductor substrate;
forming an interconnect structure over the semiconductor substrate, the interconnect structure comprising a contact pad embedded in a dielectric layer;
forming a first passivation layer over the interconnect structure;
forming a first opening through the first passivation layer to expose the contact pad;
depositing a seed layer over the first passivation layer and in the first opening;
forming a sacrificial material over the seed layer;
patterning the sacrificial material to reform the first opening and to form a second opening;
depositing conductive material to form a first redistribution line in the first opening and a second redistribution line in the second opening;
removing the sacrificial material; and
attaching an integrated circuit die to the first redistribution line and the second redistribution line.

2. The method of claim 1, further comprising:
after removing the sacrificial material, forming a second passivation layer over the first redistribution line and the second redistribution line; and
planarizing the second passivation layer to be level with the first redistribution line and the second redistribution line.

3. The method of claim 2, wherein planarizing the second passivation layer comprises removing an upper portions of the first redistribution line and the second redistribution line.

4. The method of claim 3, wherein the second passivation layer comprises:
a nitride layer along the first passivation layer, the first redistribution line, and the second redistribution line;
an oxide layer over the nitride layer; and
a bulk oxide layer over the oxide layer.

5. The method of claim 4, wherein after planarizing the second passivation layer comprises leveling upper surfaces of the first redistribution line and the second redistribution line with upper surfaces of the nitride layer, the oxide layer, and the bulk oxide layer.

6. The method of claim 1, wherein attaching the integrated circuit die comprises:
direct bonding a first die connector of the integrated circuit die to the first redistribution line; and
direct bonding a second die connector of the integrated circuit die to the second redistribution line.

7. The method of claim 1, wherein attaching the integrated circuit die comprises direct bonding a third redistribution line of the integrated circuit die to the first redistribution line and the second redistribution line.

8. The method of claim 1, wherein the second redistribution line is a dummy redistribution line.

9. The method of claim 1, further comprising, before depositing the seed layer, depositing a barrier layer along the first passivation layer and the contact pad.

10. A semiconductor device comprising:
a first integrated circuit die comprising:
a first interconnect structure over a device layer, the first interconnect structure comprising a first contact pad;
a first passivation layer over the first interconnect structure;
a second passivation layer over the first passivation layer; and
a first redistribution line extending from an upper surface of the second passivation layer to the first contact pad; and
a second integrated circuit die attached to the first integrated circuit die, a conductive feature of the second integrated circuit die being direct bonded to the first redistribution line, a dielectric layer of the second integrated circuit die being direct bonded to the second passivation layer.

11. The semiconductor device of claim 10, wherein the first integrated circuit die further comprises a second redistribution line extending from the upper surface of the second passivation layer to an upper surface of the first passivation layer.

12. The semiconductor device of claim 11, wherein the conductive feature is a third redistribution line.

13. The semiconductor device of claim 12, wherein the second integrated circuit die further comprises a second interconnect structure over and electrically connected to the third redistribution line, and wherein the second interconnect structure comprises a second contact pad being in physical contact with the third redistribution line.

14. The semiconductor device of claim 10, wherein the conductive feature is a die connector comprising a bond pad and a via, and wherein the second integrated circuit die further comprises:
a third redistribution line over and electrically connected to the via;
a second interconnect structure over and electrically connected to the third redistribution line; and
a second device layer over and electrically connected to the second interconnect structure.

15. The semiconductor device of claim 10, wherein the first passivation layer comprises a lower passivation layer and an upper passivation layer, and wherein the first integrated circuit die further comprises passive devices disposed along an interface between the lower passivation layer and the upper passivation layer.

16. A semiconductor device comprising:
a first integrated circuit comprising a first device layer and a first interconnect structure;
a second integrated circuit electrically connected to the first integrated circuit, the second integrated circuit comprising a second device layer and a second interconnect structure; and
a bonding region interposed between the first interconnect structure and the second interconnect structure, the bonding region comprising:
a first passivation layer adjacent to the first interconnect structure;
first redistribution lines embedded in the first passivation layer;
a second passivation layer adjacent to the second interconnect structure, the second passivation layer being bonded to the first passivation layer; and
second redistribution lines embedded in the second passivation layer, the second redistribution lines being bonded to the first redistribution lines.

17. The semiconductor device of claim 16, wherein the first redistribution lines comprise a first active redistribution line and a first dummy redistribution line, wherein the second redistribution lines comprise a second active redistribution line and a second dummy redistribution line, and wherein the first dummy redistribution line and the second dummy redistribution line are electrically isolated from the first integrated circuit and the second integrated circuit.

18. The semiconductor device of claim 17, wherein the first active redistribution line is direct bonded to the second active redistribution line, and wherein the first dummy redistribution line is directed bonded to the second dummy redistribution line.

19. The semiconductor device of claim 18, wherein the first redistribution lines further comprise a third active redistribution line, and wherein the third active redistribution line is direct bonded to the second active redistribution line.

20. The semiconductor device of claim 16, wherein some of the first redistribution lines are in physical contact with the second passivation layer, and wherein some of the second redistribution lines are in physical contact with the first passivation layer.
